(19) United States
(12) Patent Application Publication
(10) Pub. No.: US 2026/0068233 A1
(43) Pub. Date: Mar. 5, 2026

(54) SEMICONDUCTOR MEMORY DEVICE AND METHOD OF FABRICATING THE SAME

(71) Applicant: UNITED MICROELECTRONICS CORP., Hsin-Chu City (TW)

(72) Inventors: Chia-Chun Ke, Kaohsiung City (TW); Huang-Ren Wei, Tainan City (TW); Chung-Yi Chiu, Tainan City (TW)

(73) Assignee: UNITED MICROELECTRONICS CORP., Hsin-Chu City (TW)

(21) Appl. No.: 18/912,608

(22) Filed: Oct. 11, 2024

(30) Foreign Application Priority Data
Sep. 5, 2024 (TW) 113133576

(51) Int. Cl. H01L 29/423; H10B 41/30

(52) U.S. Cl. CPC H10D 30/6892; H10B 41/30

(57) ABSTRACT

A semiconductor memory device and a fabricating method thereof includes a substrate, two floating gates, two controlling gates, a first dielectric layer, two controlling gates, a spacer, and an erase gate. The floating gates are disposed on the substrate. The controlling gates are respectively disposed on the two floating gates. The first dielectric layer is disposed between the two floating gates and the two controlling gates in a vertical direction. The spacer is disposed on a sidewall of each of the two controlling gates. The erase gate is disposed on the substrate, between the two floating gates, wherein each of the two floating gates includes a sidewall with a scallop-shaped surface facing the erase gate.

### BACKGROUND OF THE INVENTION

### 1. Field of the Invention

The present invention relates to the field of a semiconductor memory device and a method of fabricating the same, and more particular to a semiconductor memory device comprising a flash memory and a method of fabricating the same.

### 2. Description of the Prior Art

A flash memory is a type of memory that can be erased and reprogrammed in blocks instead of one byte at a time. A typical flash memory includes a memory array, which includes a large number of memory cells. Each of the memory cells includes a floating gate field-effect transistor capable of holding charge. The cells are usually grouped into blocks. Each of the cells within a block can be electrically programmed in a random basis by charging the floating gate. The data in a cell is determined by the presence or absence of the charge in the floating gate. The charge can be removed from the floating gate by a block erase operation. Common types of flash memory cells include stacked-gate flash memory cells and split-gate flash memory cells (e.g., a third generation SUPERFLASH (ESF3) memory cell). Split-gate flash memory cells have lower power consumption, higher injection efficiency, less susceptibility to short channel effects, and over erase immunity compared to stacked-gate flash memory cells. However, the disadvantage of the existing ESF3 memory cell is that it is necessary to provide a source line contact on the strap cell between two adjacent control gate lines, which may lead to shorting between the erase gate line and the source line. Therefore, currently available technologies need to be further improved to effectively enhance component properties of semiconductor memory devices for application in specific devices.

### SUMMARY OF THE INVENTION

An object of the present invention is to provide a semiconductor memory device and a method of fabricating the same, in which two floating gates each includes a sidewall with a scallop-shaped surface facing an erase gate, to effectively increase the electron releasing speed, as well as to reduce the cell size of a memory cell, of the semiconductor memory device. Accordingly, the semiconductor memory device will therefore achieve excellent operational performance and device efficacy.

In order to achieve the above and further objects, a semiconductor memory device is provided according to the present invention. The semiconductor memory device includes a substrate, two floating gates, two controlling gates, a first dielectric layer, and a spacer. The two floating gates are disposed on the substrate. The two controlling gates are respectively disposed on the two floating gates. The first dielectric layer is disposed between the two floating gates and the two controlling gates in a vertical direction. The spacer is disposed on a sidewall of each of the two controlling gates. The erase gate is disposed on the substrate, between the two floating gates. Each of the two floating gates includes a sidewall with a scallop-shaped surface facing the erase gate.

In order to achieve the above and further objects, a method of fabricating a semiconductor memory device is provided according to the present invention. The method of fabricating the semiconductor memory device includes the following steps. A substrate is provided. Two floating gates are formed on the substrate. Two controlling gates are respectively formed on the two floating gates. A first dielectric layer is formed between the two floating gates and the two controlling gates in a vertical direction. A spacer is formed on a sidewall of each of the two controlling gates. An erase gate is formed on the substrate, between the two floating gates, wherein a scallop-shaped surface is formed on a sidewall of each of the floating gates through a Bosch etching process.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic cross-sectional view of a semiconductor memory device according to a preferred embodiment of the present invention;

FIG. 2 to FIG. 10 are schematic diagrams illustrating a method of fabricating a semiconductor memory device according to a preferred embodiment of the present invention, wherein:

FIG. 2 is a cross-sectional view schematically illustrating a semiconductor memory device after forming an opening;

FIG. 3 is a schematic diagram illustrating a semiconductor memory device after forming a spacer;

FIG. 4 is a schematic diagram illustrating a semiconductor memory device after forming a recess;

FIG. 5 is a schematic diagram illustrating a semiconductor memory device after forming a polymer layer;

FIG. 6 is a schematic diagram illustrating a semiconductor memory device after forming a scallop-shaped surface;

FIG. 7 is a schematic diagram illustrating a semiconductor memory device after forming a dielectric material layer;

FIG. 8 is a schematic diagram illustrating a semiconductor memory device after partially removing a dielectric material layer;

FIG. 9 is a schematic diagram illustrating a semiconductor memory device after forming an erase gate; and

FIG. 10 is a schematic diagram illustrating a semiconductor memory device after forming another dielectric material layer.

### DETAILED DESCRIPTION

To provide a better understanding of the present invention, preferred embodiments will be described in detail. The preferred embodiments of the present invention are illustrated in the accompanying drawings with numbered elements. In addition, the technical features in different embodiments described in the following may be replaced, recombined, or mixed with one another to constitute another embodiment without departing from the spirit of the present invention.

Please refer to FIG. 1, which is a cross-sectional diagram schematically illustrating a semiconductor memory device 10 according to a preferrable embodiment of the present invention. The semiconductor memory device 10 includes a substrate 100, two floating gates 110, two controlling gates 116, a first dielectric layer 114, a spacer 120, and an erase gate 124. The substrate 100 for example includes a silicon substrate, a silicon containing substrate (for example including SiC) or a silicon-on-insulator substrate. The floating gates 110, the first dielectric layer 114 and the controlling gates 116 are sequentially disposed on the substrate 100. Each of the controlling gates 116 is for example disposed on each of the floating gates 110, and the spacer 120 is further disposed on a sidewall 116s of each of the controlling gates 116, also on each of the floating gates 110, such that, the first dielectric layer 114 is between the two floating gates 110 and the spacer 120, and also between the two floating gates 110 and the two controlling gates 116 in a vertical direction (not shown in the drawings) being vertical to the substrate 100. On the other hand, the erase gate 124 is also disposed on the substrate 100, between the two floating gates 110. It is noted that, each of the floating gates 110 includes a sidewall 110s having a scallop-shaped surface 112 thereon being facing the erase gate 124. Through these arrangements, the controlling gates 116 and the floating agates 110 disposed at two sides of the erase gate 124 will together form two memory gates, with each controlling gate 116 controlling the voltage, with each floating gate 110 storing the electrons, and with the erase gate releasing the electrons. In this way, the semiconductor memory device 10 enables to serve as a flash memory device, to promote the tip discharge from the scallop-shaped surface 112 of the floating gates 110 by increasing the local electric field, such that the electron releasing speed is increased, and the ability of erasing electron of the semiconductor memory device 10 is improved thereby.

Precisely speaking, the sidewall 110s of each floating gate 110 includes a plurality of protrusions 112t extending toward the erase gate 124, and the tip of each of the protrusions 112t extends beyond a sidewall 120s of the spacer 120, such that the sidewall 110s of each floating gate 110 will therefore present in the scallop-shaped surface 112 as shown in FIG. 1 for increasing the tip discharge. In one embodiment, a distance W1 between the tip of each of the protrusions 112t and the sidewall 120s of the spacer 120 is the same with each other, but not limited thereto. In another embodiment, the distance W1 between the tip of each of the protrusions 112t and the sidewall 120s of the spacer 120 may also be different from one another, with the distance W1 between the tip of each protrusion 112t and the sidewall 120s of the spacer 120 being gradually increased or decreased from top to bottom along the vertical direction being perpendicular to the substrate 100.

Further in view of FIG. 1, the semiconductor memory device 10 further includes an insulating layer 102, a blocking layer 118, a second dielectric layer 122 and a third dielectric layer 126. The insulating layer 102 is disposed between the floating gates 110 and the substrate 100, to electrically isolate the floating gates 110 and the substrate 100, and the erase gate 124 penetrates through the insulating layer 102 to directly contact the substrate 100 underneath. The erase gate 124 includes a top surface 124t being lower than a top surface 116t of each controlling gate 116, and the blocking layer 118 is disposed on the top surface 116t of each controlling gate 116, with the sidewall of the blocking layer 118 being also covered by the spacer 120. On the other hand, the second dielectric layer 122 entirely covers the two controlling gates 116 and the two floating gates 110, and is partially disposed between the erase gate 124 and the two floating gates 110, such that, the second dielectric layer 122 will overlay the sidewall 110s of each floating gate 110, with a portion of the second dielectric layer 122 between sandwiched between each of the protrusions 112t for isolating the erase gate 124 and the two floating gates 110 at two sides of the erase gate 124. The third dielectric layer 126 is disposed on the second dielectric layer 122 and the erase gate 126, overlaying the two controlling gates 116 and the erase gate 126. In one embodiment, the two controlling gates 116 and the two floating gates 110 for example respectively includes a conductive material like doped polysilicon, the erase gate 124 for example includes a metal material like tungsten, and the insulating layer 102, the first dielectric layer 114 and the blocking layer 118 for example respectively include a dielectric material, and preferably include the same dielectric material like silicon oxide, but not limited thereto. In another embodiment, the third dielectric layer 126 and the second dielectric layer 122 for example include a dielectric material, and preferably include the same dielectric material like high temperature oxide (HTO), but not limited thereto.

According to the semiconductor memory device 10 of the present embodiment, the two memory gates (each including one floating gate 110 and one controlling gate 116 stacked in sequence) are disposed at two sides of the erase gate 124 in a symmetrical manner, so as to configure as the flash memory device. In this way, through arranging the scallop-shaped surface 112 extending toward the erase gate 124 on the sidewall of the floating gate 110 of each memory gate, the tip discharge is promoted by increasing the local electric field thereof, and the electron releasing speed is increased, and the ability of erasing electron of the semiconductor memory device 10 is effectively improved thereby. In addition, the semiconductor memory device 10 of the present embodiment includes a simplify configuration as in comparison with that of other flash memory device (such as an ESF3 memory cell), so as to obtain a reduced size of the memory cell. Also, in another embodiment, the semiconductor memory device 10 may additionally include a source line (not shown in the drawings) disposed within the substrate 100, right below the erase gate 124, and word lines (not shown in the drawings) and bit lines (not shown in the drawings) disposed both at two opposite sides of the two memory gates, for providing various voltages. Accordingly, the semiconductor memory device 10 will therefore serve an ESF3 memory cell (not shown in the drawings), and which also enables to promote the tip discharge, to increase the electron releasing speed, and to improve the ability of erasing electron thereof, through arranging the scallop-shaped surface 112 facing the erase gate 124 on the sidewall of the floating gate 110.

In order to make those having ordinary skills in the art easily understand the semiconductor memory device 10 according to the present disclosure, a fabricating method of the semiconductor memory device 10 according to the present disclosure will be further described as follows.

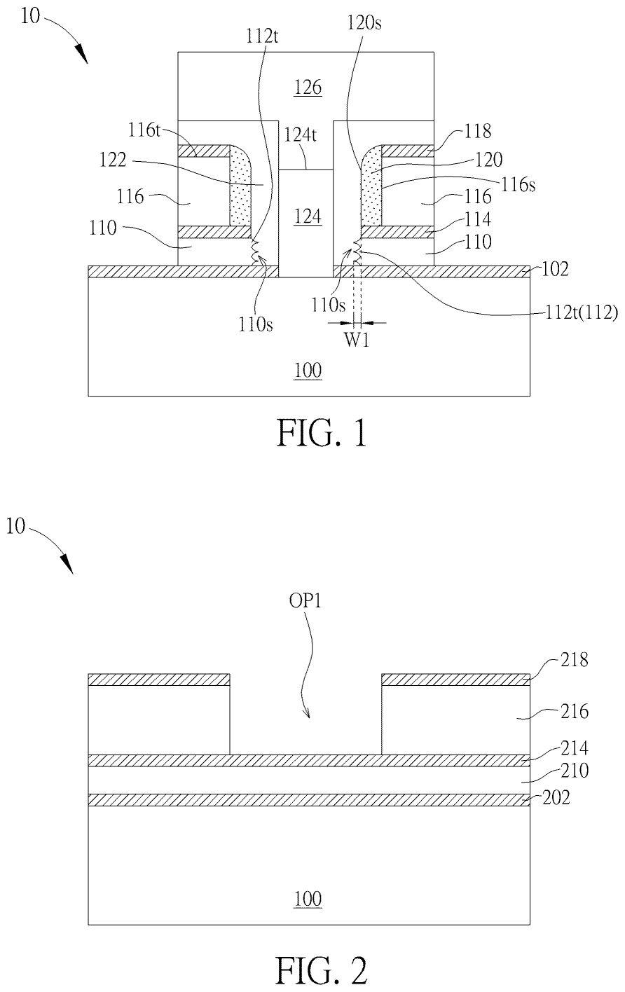

Please refer to FIG. 2 to FIG. 10, which are schematic diagrams illustrating a method of fabricating the semiconductor memory device 10 according to a preferably embodiment of the present disclosure. Firstly, as shown in FIG. 2, the substrate 100 is provided, and an insulating material layer 202, a first conductive layer 210, a first dielectric material layer 214, a second conductive layer 216, and a blocking material layer 218 are sequentially formed on the substrate 100. Next, a patterning process is performed through a mask layer (not shown in the drawings), to partially remove the blocking material layer 218 and the second conductive layer 216, to form a first opening OP1 for partially exposing the first dielectric material layer 214 underneath. Then, the mask layer is completely removed. In one embodiment, the second conductive layer 216 and the first conductive layer 210 for example respectively include a conductive material like doped polysilicon, and the blocking material layer 218, the first dielectric material layer 214 and the insulating material layer 202 for example respectively include a dielectric material, and preferably include the same dielectric material like silicon oxide, but not limited thereto.

As shown in FIG. 3, a spacer 120 is formed on sidewalls of the first opening OP1. The formation of the spacer 120 includes but not limited to the following steps. Firstly, a deposition process is performed on the substrate 100, to form a spacer material layer, partially formed withing the first opening OP1 and partially formed outside the first opening OP1, overlaying the blocking material layer 218. Next, an etching back process is performed, to partially remove the spacer material layer formed within the first opening OP1, and to completely remove the spacer material layer formed outside the first opening OP1, to form the spacer 120. In one embodiment, the spacer material layer for example includes a dielectric material being different from that o the blocking material layer 218, the first dielectric material layer 214 or the insulating material layer, such as including silicon nitride, but not limited thereto.

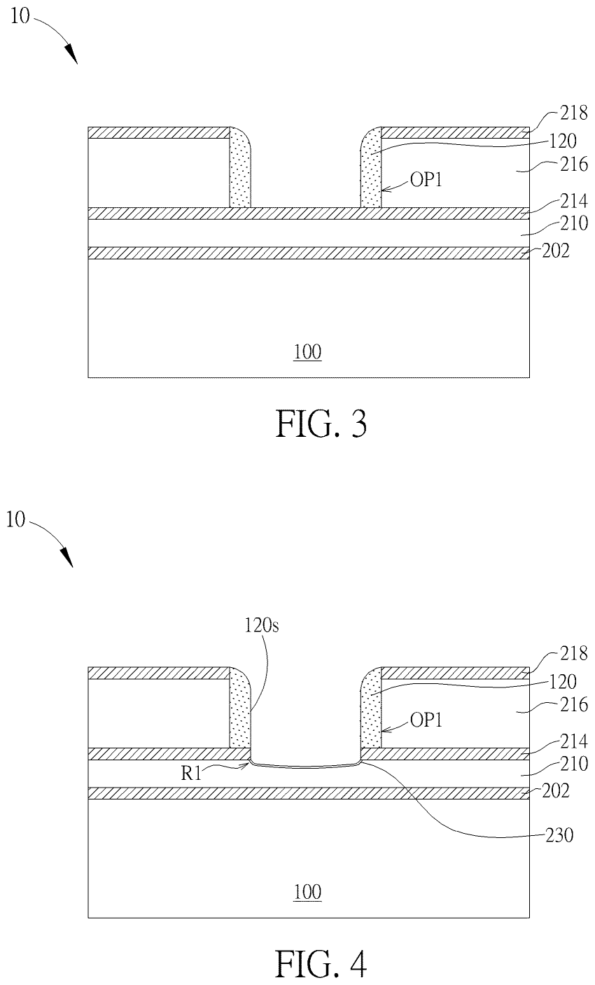

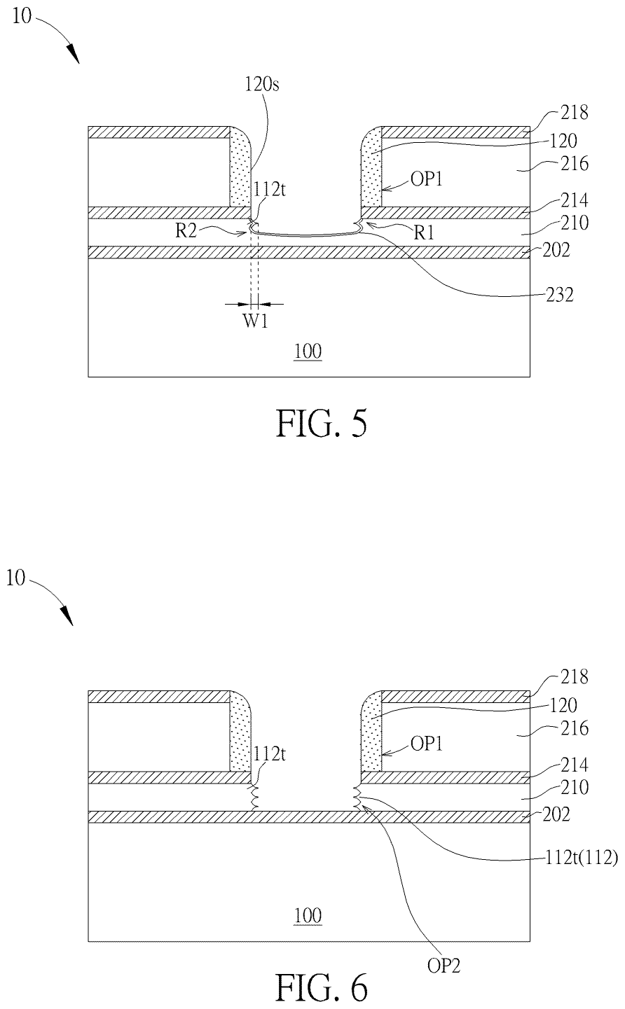

As shown in FIG. 4 to FIG. 6, a Bosch etching process is performed to form a second opening OP2 as shown in FIG. 6, within the first conductive layer 210, with sidewalls of the second opening OP2 having the scallop-shaped surface 112. Precisely speaking, firstly as shown in FIG. 4, a first etching process such as a dry etching process is performed through the first opening OP1, to remove the first dielectric material layer 214 exposed from the first opening OP1, and to partially remove the first conductive layer 210 under the first dielectric material layer 214, to form a first recess R1 within the first conductive layer 210. The first recess R1 for example includes a disk-shaped cross-section as shown in FIG. 4, with two sides thereof being vertically aligned with sidewalls 120s of the spacer 120, respectively. Next, a polymer layer 230 is formed on the first recess R1, conformally overlaying surfaces of the first recess R1. In one embodiment, the polymer 230 for example includes a material like silicon oxide or silicon oxynitride, but not limited thereto.

Then, as shown in FIG. 5, a second etching process such as a dry etching is performed through the polymer layer 230, penetrating through the polymer layer 230 through the second etching process, followed by further etching the first conductive layer 210 underneath, to form a second recess R2 below the first recess R1. The second recess R2 for example includes a disk-shaped cross-section as shown in FIG. 5, and a boundary between the first recess R1 and the second recess R2 will form the protrusion 112t extending toward the center of the first recess R1 or the second recess R2. The tip of the protrusion 112t extends beyond one corresponding sidewall 120s of the spacer 120. In one embodiment, there is the distance W1 between the tip of the protrusion 112t and the corresponding sidewall 120s of the spacer 120, but not limited thereto. Next, a polymer layer 232 is further formed on the first recess R1 and the second recess R2, conformally overlaying the surfaces of the first recess R1 and the second recess R2. In one embodiment, the polymer layer 232 also includes the material like silicon oxide or silicon oxynitride, but not limited thereto.

As shown in FIG. 6, a third etching process such as a dry etching process is performed through the polymer layer 232, penetrating through the polymer layer 232 through the third etching process, followed by further etching the first conductive layer 210 underneath, to form another disk-shaped recess (not shown in the drawings) below the second recess R2. Then, forming another polymer layer (not shown in the drawings) and carrying out another etching process through the another polymer layer are repeatedly performed, till the second opening OP2 is formed within the first conductive layer 210. With these performances, the second opening OP2 is formed by forming a plurality of disk-shaped recesses stacked downwardly in sequence, and a plurality of the protrusions 112 is formed on the sidewall of the second opening OP2 from the boundaries of the disk-shaped recesses, thereby presenting in the scallop-shaped surface 112 as a whole, as shown in FIG. 6. In one embodiment, the distance W1 between the tip of each protrusion 112t and the corresponding sidewall 120s of the spacer 120 may be optionally the same as or different from each other, but not limited thereto. For example, the distance W1 between the tip of each protrusion 112t and the corresponding sidewall 120s of the spacer 120 may be gradually increased or decreased from top to bottom, but not limited thereto.

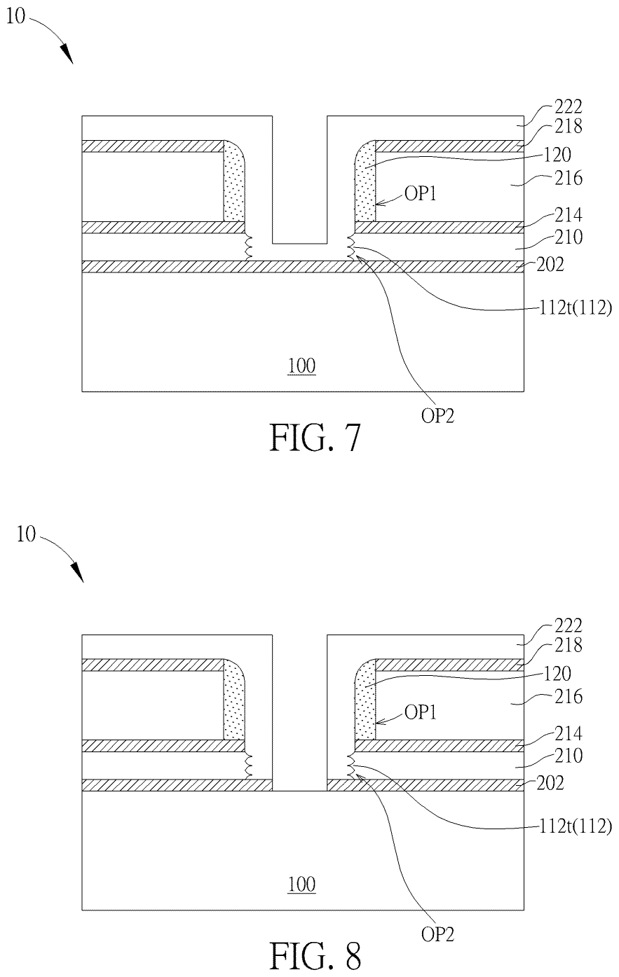

As shown in FIG. 7, a deposition process such as a high temperature oxidation (HTO) process is performed, to form a second dielectric material layer 222 on the substrate 100, partially within the first opening OP1 and the second opening OP2, and partially outside the first opening OP1 and the second opening OP2. Precisely speaking, the second dielectric material layer 222 is formed by conformally overlaying the blocking material layer 218, the spacer 120 and the insulating material layer 202, and further overlaying the scallop-shaped surface 112 of the second opening OP2, such that, a portion of the second dielectric material layer 222 will be sandwiched between each of the protrusions 112t. In one embodiment, the second dielectric material layer 222 for example includes a dielectric material like high temperature oxide, but not limited thereto.

As shown in FIG. 8, an etching process is performed to partially remove the second dielectric material layer 222 formed within the second opening OP2, and the insulating material layer 202 under the removed second dielectric material layer 222, to partially expose the substrate 100 underneath. In one embodiment, an ion implanted process may be optionally performed in the substrate 100, to form a doped region (not shown in the drawings) in the exposed portion of the substrate 100 for directly contacting the erase gate 124 formed in the subsequent process.

As shown in FIG. 9, the erase gate is formed in the first opening OP1 and the second opening OP2, to directly contact the exposed portion of the substrate 100. The formation of the erase gate 124 includes but not limited to the following steps. Firstly, a deposition process is performed, to form a conductive material layer (not shown in the drawings) at least filling up the first opening OP1 and the second opening OP2, and the conductive material layer filling in the first opening OP1 is partially removed, to form the erase gate 124 with a top surface 124t being lower than the top surface of the second conductive layer 216. In one embodiment the conductive material layer for example includes a metal material like tungsten but not limited thereto.

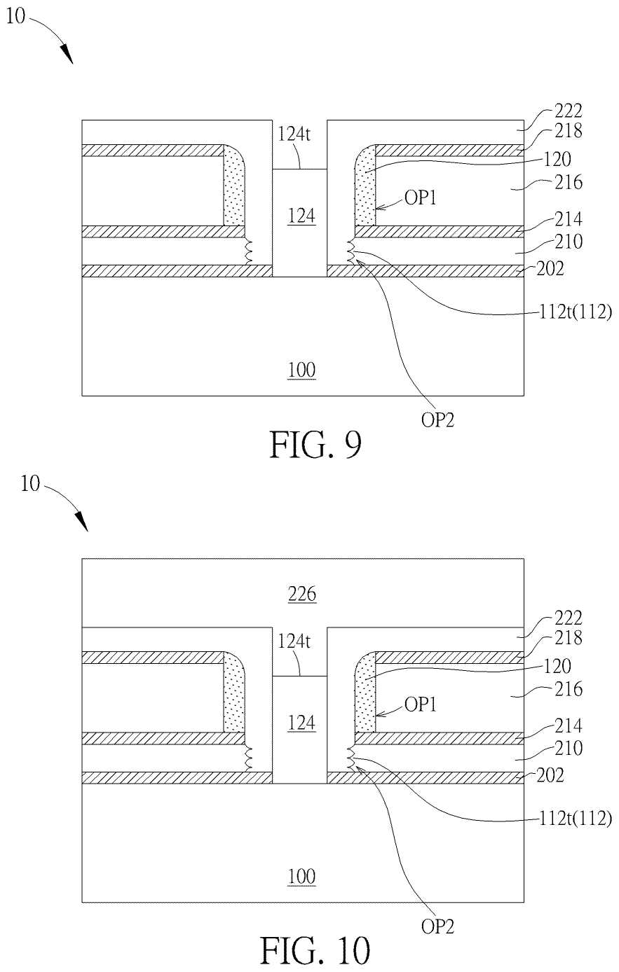

As shown in FIG. 10, another high temperature oxidation process is performed, to form a third dielectric material layer 226 on the second dielectric material layer 222 and the erase gate 124, with the third dielectric material layer 226 filling in the rest space of the first opening OP1 and further overlaying the top surface of the second dielectric material layer 222. In one embodiment, the third dielectric material layer 222 for example includes a dielectric material, preferably includes the same dielectric material as that of the second dielectric material layer 222, such as being high temperature oxide, but not limited thereto. Following these, another mask layer (not shown in the drawings) is formed on the third dielectric material layer 226, with the another mask layer entirely covering the erase gate 124 and partially covering the third dielectric material layer 226, the second dielectric material layer 222, the blocking material layer 218, the second conductive layer 216, the first dielectric material layer 214, the first conductive layer 210 and the insulating material layer 202 at two sides of the erase gate 124, and the third dielectric material layer 226, the second dielectric material layer 222, the blocking material layer 218, the second conductive layer 216, the first dielectric material layer 214, the first conductive layer 210 and the insulating material layer 202 stacked in sequence are patterned through the another mask layer, to form the third dielectric layer 126, the second dielectric layer 122, the blocking layer 118, the two controlling gates 116, the first dielectric layer 114, the two floating gates 110 and the insulating layer 102 as shown in FIG. 1. Then, the method of fabricating the semiconductor memory device 10 is accomplished thereby.

According to the method of fabricating the semiconductor memory device 10 in the present embodiment, the two memory gates (each including one floating gate 110 and one controlling gate 116 stacked in sequence) being symmetrical with each other are formed at two sides of the erase gate 124, so that the semiconductor memory device 10 may therefore serve as the flash memory device. In this way, through performing the Bosch etching process, the scallop-shaped surface 112 extending toward the erase gate 124 is formed on the sidewall of the floating gate 110 of each memory gate, so as to promote the tip discharge, and to increase the electron releasing speed. Then, the semiconductor memory device 10 formed thereby will therefore obtain an improve ability of erasing electron. In addition, the semiconductor memory device 10 fabricated in the present embodiment further includes a simplify configuration as in comparison with that of other flash memory device (such as an ESF3 memory cell), so as to obtain a reduced size of the memory cell for achieving excellent operational performance and device efficacy thereby.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor memory device, comprising:
a substrate;
two floating gates, disposed on the substrate;
two controlling gates, respectively disposed on the two floating gates;
a first dielectric layer, disposed between the two floating gates and the two controlling gates in a vertical direction;
a spacer, disposed on a sidewall of each of the two controlling gates; and
an erase gate, disposed on the substrate, between the two floating gates;
wherein each of the two floating gates comprises a sidewall, and the sidewall comprises a scallop-shaped surface facing the erase gate.

2. The semiconductor memory device according to claim 1, wherein the sidewall comprises a plurality of protrusions toward the erase gate, and each of the protrusions comprises a tip extends beyond a sidewall of the spacer.

3. The semiconductor device according to claim 2, wherein the protrusions comprise a same distance from the tip of each of the protrusions to the sidewall of the spacer.

4. The semiconductor device according to claim 2, wherein the protrusions comprise different distances from the tips of the protrusions to the sidewall of the spacer.

5. The semiconductor device according to claim 2, further comprising:
a second dielectric layer disposed between the erase gate and the two floating gates, wherein the second dielectric layer overlays the sidewall of each of the two floating gates.

6. The semiconductor device according to claim 5, wherein a portion of the second dielectric layer is sandwiched between the protrusions.

7. The semiconductor device according to claim 5, further comprising:
a third dielectric layer disposed on the second dielectric layer, overlaying the two controlling gates and the erase gate.

8. The semiconductor device according to claim 7, wherein the third dielectric layer comprises a material the same as that of the second dielectric layer.

9. The semiconductor device according to claim 1, wherein a top surface of the erase gate is lower than a top surface of each of the two controlling gates.

10. The semiconductor device according to claim 5, further comprising:
an insulating layer disposed on the substrate, between the two floating gates and the substrate in the vertical direction.

11. A fabricating method of a semiconductor memory device, comprising:
providing a substrate;
forming two floating gates on the substrate;
forming two controlling gates respectively on the two floating gates;
forming a first dielectric layer between the two floating gates and the two controlling gates in a vertical direction;
forming a spacer on a sidewall of each of the two controlling gates;
forming an erase gate on the substrate, between the two floating gates; and
forming a scallop-shaped surface on a sidewall of each of the floating gates through a Bosch etching process.

12. The fabricating method of the semiconductor memory device according to claim 11, further comprising:
sequentially forming a first conductive layer, a first dielectric material layer, and a second conductive layer stacked in sequence on the substrate; and
patterning the second conductive layer, to form a first opening within the second conductive layer.

13. The fabricating method of the semiconductor memory device according to claim 12, after forming the first opening, further comprising:
forming a spacer material layer, partially within the first opening and partially outside the first opening; and
partially removing the spacer material layer, to form the spacer on a sidewall of the first opening.

14. The fabricating method of the semiconductor memory device according to claim 12, wherein the Bosch etching process is performed after the spacer is formed, and the Bosch etching process further comprising:
partially removing the first dielectric material layer and the first conductive layer, to form a first recess in the first conductive layer;
forming a polymer layer covering a surface of the first recess;
performing an etching process through the polymer layer, to form a second recess below the first recess; and
repeatedly forming another polymer layer and performing another etching process through the another polymer layer, to form a second opening in the first conductive layer and a scallop-shaped surface on a sidewall of the second opening.

15. The fabricating method of the semiconductor memory device according to claim 14, wherein the erase gate is formed after the Bosch etching process is performed.

16. The fabricating method of the semiconductor memory device according to claim 15, further comprising:
conformally forming a second dielectric material layer, overlaying the scallop-shaped surface of the second opening and the spacer;
partially removing the second dielectric material layer to expose a portion of the substrate; and
forming the erase gate in the second opening and in the first opening, wherein the second dielectric layer is partially formed between the erase gate and the scallop-shaped surface of the second opening.

17. The fabricating method of the semiconductor memory device according to claim 16, after forming the erase gate, further comprising:
patterning the second conductive layer, the first dielectric layer, and the first conductive layer, to simultaneously form the two controlling gates, the first dielectric layer, and the two floating gates on the substrate.

18. The fabricating method of the semiconductor memory device according to claim 16, after forming the erase gate, further comprising:
forming a third dielectric material layer, covering the second dielectric layer and the erase gate; and
partially removing the third dielectric material layer, to form a third dielectric layer on the second dielectric layer and the erase gate.
